(19) United States
(12) Patent Application Publication
(10) Pub. No.: US 2009/0309199 A1
(43) Pub. Date: Dec. 17, 2009

(54) CHIP PACKAGE FOR SEMICONDUCTOR DEVICES

(76) Inventor: Keith Richard Barkley, Downey, CA (US)

Correspondence Address: CHRISTOPHER P. MAIORANA, P.C., 24840 HARPER SUITE 100, ST. CLAIR SHORES, MI, 48080, US

(21) Appl. No.: 12/138,298

(22) Filed: Jun. 12, 2008

(51) Int. Cl. H01L 23/495; H01L 21/60

(52) U.S. Cl. 257/676; 438/123; 257/E23.031; 257/E21.506

(57) ABSTRACT

A chip package for semiconductor devices is provided. The chip package includes a flange configured to mount thereon a semiconductor device. The chip package further includes an inverted bridge lead frame above the flange and having a recessed area below a top portion. The inverted bridge lead frame provides semiconductor device terminal connections to at least one lead.

### BACKGROUND OF THE INVENTION

This invention relates generally to chip packages for semiconductor devices, and more particularly, to isolated-chip packages for semiconductor devices.

Demand is increasing for semiconductor chip packages for industrial applications having higher efficiencies and lower cost. In some amplifier technologies, the heat transfer interface (e.g., heatsink) of the chip package must be electrically isolated from the terminals of the device to which the interface is connected. For example, in a Metal-Oxide-Semiconductor Field-Effect Transistor (MOSFET) package, the source, gate and drain terminals would be isolated from the heat transfer interface. Ceramic headers are conventionally used as the heat transfer device in typical MOSFET packaging. In a conventional package, for example, for a radio-frequency (RF) MOSFET, a ceramic header of Beryllium Oxide (BeO) is used because BeO provides good thermal conductivity and good electrical isolation. However, BeO is an expensive and hazardous material. In these conventional packages the bottom of the semiconductor chip (the drain) is connected directly to the drain leads and wire bonds are used to connect the gate and the source connections on the chip to their respective leads. There is no electrical connection to the flange of the device. The flange is used only for mechanical attachment and heat transfer.

In Laterally Diffused Metal Oxide Semiconductor (LDMOS) packages, the semiconductor device (or LDMOS die) is attached directly on a bottom surface to a heat transferring flange. The flange may be made formed from a copper-tungsten material in order to match the thermal coefficient of expansion of the semiconductor chip (e.g., silicon chip) in the package. In these packages, a window frame structure formed from, for example, Aluminum Oxide (Alumina) is used to isolate the leads of the semiconductor device from the flange. For example, wire bonds are used to connect the gate and drain terminals to terminal bonding pads on the window frame. Because the source of the semiconductor device (e.g., transistor) is connected to the bottom of the chip, the package flange is the electrical connection to the source, as well as the heatsink (i.e., the source of the transistor is connected directly to ground). This configuration prevents, for example, an LDMOS device from being used in amplifier topologies such as source followers, where the source is not connected to ground. Moreover, in order to provide an LDMOS device with an isolated source, the device packaging must use a BeO insulator, thereby negating the LDMOS packaging advantages.

It is also desirable to have chip packages with standard configurations or footprints. Changing to a new package configuration, for example, from a BeO insulated package to an LDMOS style package would also necessitate a redesign, thereby adding cost and time to the process.

### BRIEF DESCRIPTION OF THE INVENTION

In accordance with an exemplary embodiment, a chip package is provided that includes a flange configured to mount thereon a semiconductor device. The chip package further includes an inverted bridge lead frame above the flange and having a recessed area below a top portion. The inverted bridge lead frame provides semiconductor device terminal connections to at least one lead.

In accordance with another exemplary embodiment, a lead frame for a chip package is provided that includes a planar top portion having a plurality of leads. The lead frame further includes a recessed area having a lower connection portion. The lower connection portion is in a parallel and lower plane to the planar top portion.

In accordance with yet another exemplary embodiment, a method for packaging a semiconductor device is provided. The method includes mounting a semiconductor transistor device to a flange. The method further includes connecting terminals of the semiconductor transistor device to an inverted bridge lead frame, wherein source terminal connections are below both drain and gate terminal connections.

### BRIEF DESCRIPTION OF THE DRAWINGS

FIG. 1 is an exploded view of the chip package having an inverted bridge constructed in accordance with an embodiment of the invention

FIG. 2 is a side elevation view of an inverted bridge constructed in accordance with various embodiments of the invention.

FIG. 3 is a top plan view of the inverted bridge of FIG. 2.

FIG. 4 is a top plan view of the chip package of FIG. 1 having a semiconductor chip mounted therein.

FIG. 5 is a side elevation view of the chip package of FIG. 4.

FIG. 6 is an enlarged top perspective view of a portion of the chip package of FIG. 4.

FIG. 7 is a side elevation view of a chip package constructed in accordance with another embodiment of the invention.

FIG. 8 is a top plan view of the chip package of FIG. 7.

FIG. 9 is a diagram of a Metal Oxide Semiconductor Field-Effect Transistor (MOSFET) constructed in accordance with various embodiments of the invention and which may be mounted within the various chip packages of FIGS. 1 through 8.

### DETAILED DESCRIPTION OF THE INVENTION

For simplicity and ease of explanation, the invention will be described herein in connection with various embodiments thereof. Those skilled in the art will recognize, however, that the features and advantages of the various embodiments may be implemented in a variety of configurations. It is to be understood, therefore, that the embodiments described herein are presented by way of illustration, not of limitation.

As used herein, an element or step recited in the singular and proceeded with the word “a” or “an” should be understood as not excluding plural said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property. Additionally, the arrangement and configuration of the various components described herein may be modified or changed, for example, replacing certain components with other components or changing the order or relative positions of the components.

Various embodiments of the invention provide a lead frame for a chip package and a chip package for a semiconductor chip having terminals on a top surface of the semiconductor chip. The chip package of the various embodiments have lead frames that accommodate, for example, a vertical structure transistor therein having a plurality of terminals on a top surface of the transistor. The chip package is provided in a standard footprint that accommodates a semiconductor chip therein that would otherwise require a non-standard footprint. For example, the various embodiments of the invention can accommodate a power Metal Oxide Semiconductor Field-Effect Transistor (MOSFET) having terminals on a top surface thereof and maintain the topside connections in the package (instead of the source having to be connected to a bottom flange of the package).

It should be noted that the various chip package embodiments are not limited to receiving therein particular transistors or power devices and may be configured, for example, to receive therein any type of power or vertical structure transistor. For example, the various embodiments may provide a package for any vertical uni-polar structure transistor or devices, for example, wherein a ground is provided on a bottom surface of the device. Accordingly, the various embodiments are not limited to use with MOSFETs, but may be used with other transistor devices, for example, bipolar junction transistors having a collector, emitter and base instead of the drain, source and gate of the MOSFET.

The chip packages of the various embodiments can receive therein semiconductor chips (e.g., transistors) formed using different fabrication processes. For example, a Double-Diffused Metal Oxide Semiconductor (DMOS) process may be used to form a MOSFET that is packaged in accordance with various embodiments of the invention.

Various embodiments of the invention provide a chip package with lead frame for bottom-side isolated semiconductor devices, for example, vertical transistors having top-side terminals on the semiconductor chip. In the various embodiments, isolated configurations are provided such that the bottom-side isolated semiconductor devices can be provided, for example, in industry standard isolated packages such as the RF power MOSFET MRF150 from M/A-Corn, Inc. Various embodiments of isolated packages may be provided, for example, depending on the layouts of the source pads on the semiconductor chip.

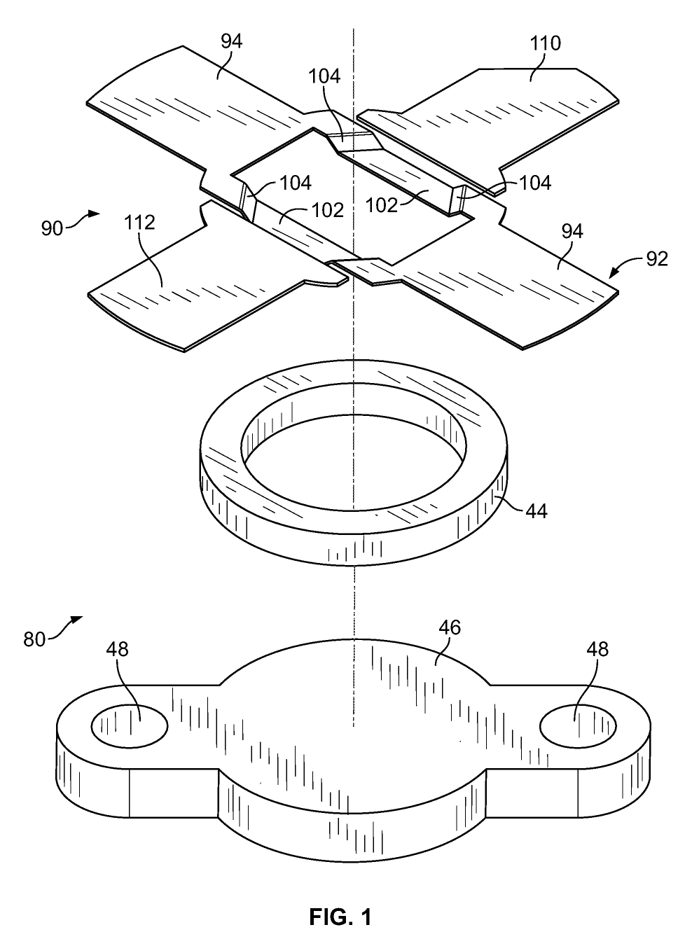

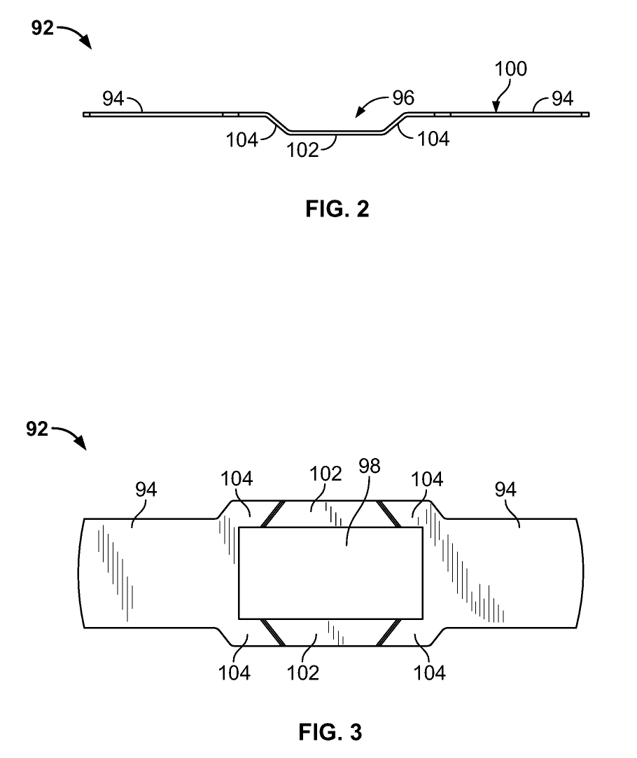

For example, as shown in FIGS. 1 through 6, a chip package 80 is provided that includes an inverted bridge lead frame 90 (shown specifically in FIGS. 1, 2, 3 and 6) that may be used when source pads 30 of a semiconductor chip 32 are located along two opposite sides (e.g., lengthwise or longitudinally along a top surface) of the semiconductor chip 32. Specifically, the lead frame 90 as shown in FIGS. 2 and 3 includes a source portion 92 having source leads 94. A middle region 96 includes an opening 98 for receiving therethrough the semiconductor chip 32. The opening 98 is formed between the source leads 94. The middle region 96 includes a recessed area below a top surface 100 of the source portion 92. The recessed area includes lower connection portions 102 below the top surface 100. Angled portions 104 (e.g., angled walls) extend between the top surface 100 and the lower connection portions 102. It should be noted that the angled portions may be angled at any degree greater than zero degrees and less than 180 degrees. The angled portions 104 may angle inward or outward.

Thus, the lead frame 90 (shown fully in FIG. 1) includes source leads 94 along the top surface 100 in a first plane and the lower connection portions 102 in a second plane below the first plane that define planar connection regions. In various embodiments the first and second planes are parallel. In other embodiments the first and second planes are not parallel. Optionally, the top surface 100 and/or the lower connection portions 102 may not be planar, but instead may be, for example, curved.

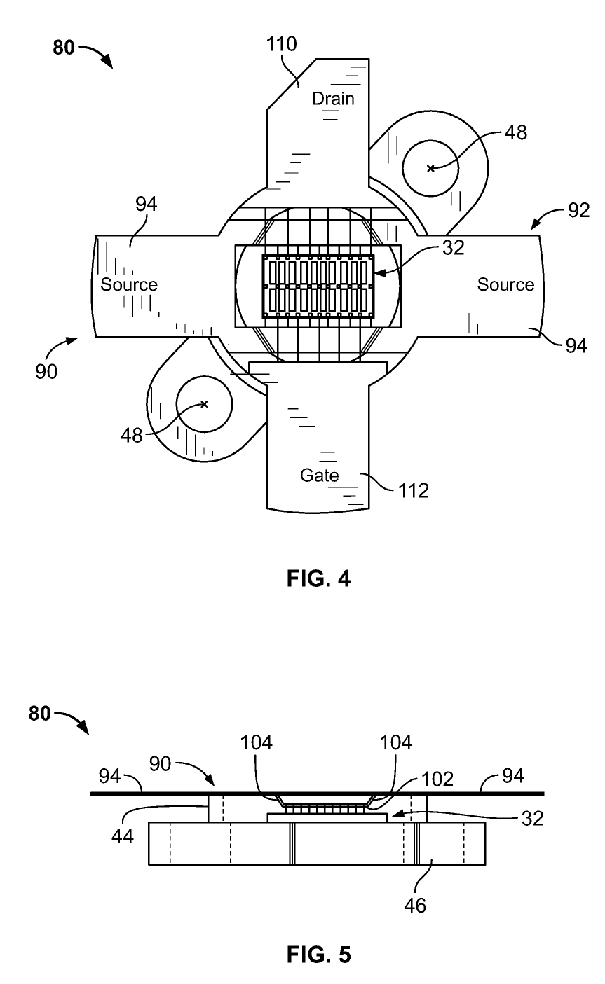

The lead frame 90 also includes a drain lead 110 and a gate lead 112 as shown in FIGS. 1 and 4. The lead frame 90 is mounted on a window frame 44. The window frame 44 is mounted to the flange 46, for example, a copper/tungsten flange. The flange 46 may include openings 48 that may be used to mount the chip package 80 onto, for example, a printed circuit board or other system board. The semiconductor chip 32 is mounted directly to the flange 46, for example, to a copper pad (not shown).

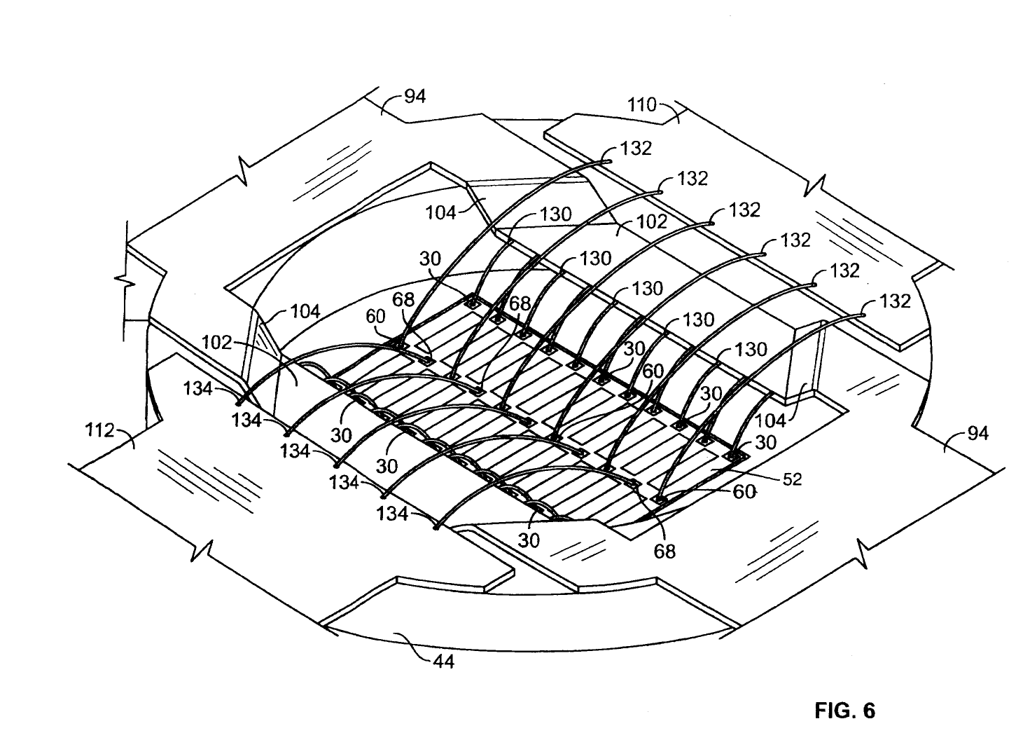

As can be seen, the lead frame 90 is supported generally horizontally above the flange 46 by the window frame 44 (e.g., an Alumina Oxide frame). The top portion 100 of lead frame 90 accordingly extends in a plane generally above and parallel to the surface of the flange 46 and the lower connection portions 102 extend in a plane below the plane of the top portion 100 and also parallel to the surface of the flange 46. Thus, this inverted bridge structure is used to lower the level of the source connections below the level of the drain and gate connections as shown, for example, in enlarged view in FIG. 6. Different connections are thereby provided at different levels within the chip package 80.

It should be noted that the semiconductor chip 32 may be any shape, for example, square or triangular. The source pads 30 are connected directly to the lower connection portion 102 of the lead frame 90 as shown more clearly in FIG. 6. In particular, the source pads 30 on each side of the top surface of the semiconductor chip 32 are wire bonded to the lower connection portion 102 using wire bonds 130. The wire bonds 130 extend generally upward from the top surface 52 of the semiconductor chip 32 to the lower connection portion 102 to make the source connections.

Additionally, drain pads 60 along a middle of the top surface of the semiconductor chip 32 between the sides are wire bonded to an adjacent drain lead 110 using wire bonds 132. Further, gate pads 68 along the middle of the top surface of the semiconductor chip 32 between the sides are wire bonded to an adjacent gate lead 112 using wire bonds 134. It should be noted that the wire bonds 130 on each of the sides extend in generally the same direction as the wire bonds 132 and wire bonds 134. However, the wire bonds 132 and 134 extend and connect higher on the lead frame 90 than the wire bonds 130.

It should be noted that the number of pads on the semiconductor chip 32 and the number of wire bonds are not limited to the number shown. More or less pads and wire bonds may be provided, for example, depending on the type of semiconductor chip 32. Also, the positioning of the pads along the top surface of the semiconductor chip 32 may be changed and the positioning of the leads of the lead frame 90 relative to the window frame 44 changed accordingly. Additionally, although the leads are positioned at ninety degrees relative to each other, different positioning may be provided. The leads also may be shaped and sized differently.

The chip package 90 may be formed from one or more pieces permanently secured together. For example, referring again to FIG. 1, each of the flange 46, window frame 44, source portion 92, drain lead 110 and gate lead 112 may be separate components. The components may be secured together in any suitable manner, for example, by brazing, epoxy, etc. to form a single unitary chip package 90. It should be noted that the shapes and sizes of the various components may be modified as desired or needed. For example, the window frame 44 may be square or rectangular instead of circular. It also should be noted that the chip package 90 does not include any insulation or insulating layer.

The chip package 90 may be constructed having an industry standard footprint, for example, configured as an MRF150-style package with the leads positioned in a standard configuration and the semiconductor chip 32 being a bottom-side isolated vertical transistor with top-side terminals. Accordingly, the package dimensions and connections can conform to industry standards for non-insulated chip packages while packaging a vertical semiconductor transistor.

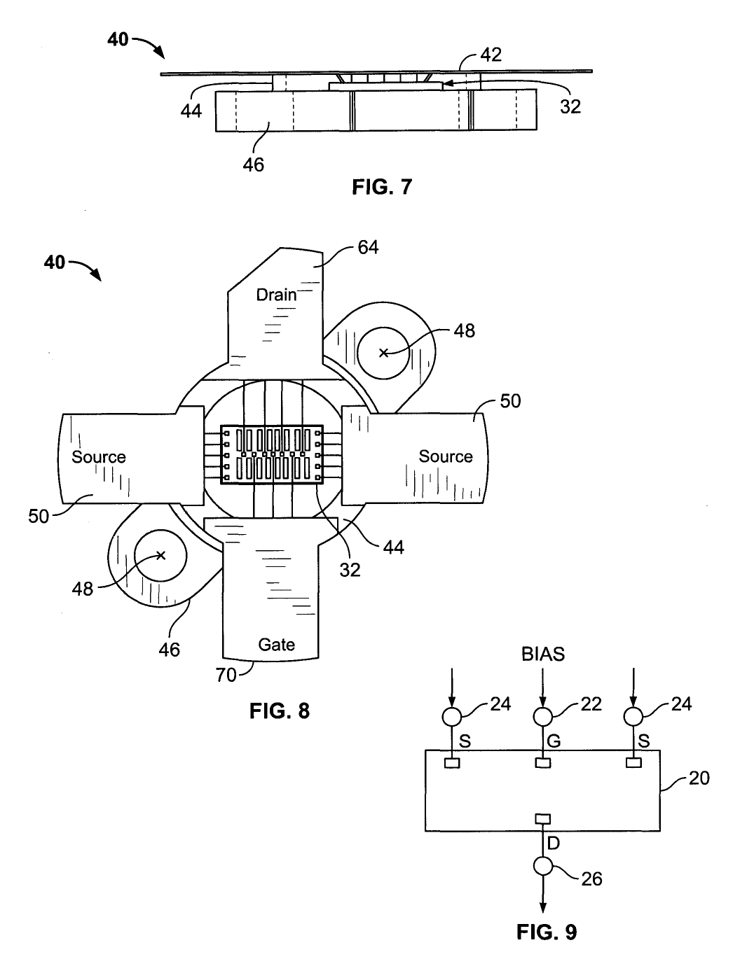

In another embodiment, as shown in FIGS. 7 and 8, a chip package 40 may be provided if the source pads 30 of the semiconductor chip 32 (e.g., bottom-side insulated MOSFET chip) are located on one or more different opposite sides (e.g., transverse sides) of the semiconductor chip 32. When reference is made herein to pads of the semiconductor chip 32, this can refer to any type of connection terminal.

Specifically, as shown in FIGS. 7 and 8, a lead frame 42 is mounted on the window frame 44. The window frame 44 is mounted to the flange 46, for example, a copper/tungsten flange. The flange 46 may include one or more openings 48 that may be used to mount the chip package 40 onto, for example, a printed circuit board or other system board. The semiconductor chip 32 is mounted directly to the flange 46, for example, to a copper pad (not shown). However, unlike the lead frame 90 shown in FIGS. 1 through 6 (and described above), the lead frame 42 is a single planar structure.

As can be seen, the lead frame 42 is supported generally horizontally above the flange 46 by the window frame 44 (e.g., an Alumina Oxide frame). The lead frame 42 accordingly extends in a plane generally above and parallel to the surface of the flange 46. In this embodiment, the source pads are connected directly to one or more source leads 50 of the lead frame 42. For example, the source pads on each of two sides of the top surface of the semiconductor chip 32 are wire bonded to adjacent source leads 50 using wire bonds. The source pads 30 may be provided on opposite transverse sides of the semiconductor chip 32. Additionally, drain pads along a different portion of the semiconductor chip 32, for example, the middle of the top surface of the semiconductor chip 32 between the longitudinal sides, are wire bonded to an adjacent drain lead 64 using wire bonds. Further, gate pads also along the middle of the top surface of the semiconductor chip 32 between the longitudinal sides, are wire bonded to an adjacent gate lead 70 using wire bonds.

It should be noted that the number of pads on the semiconductor chip 32 and the number of wire bonds are not limited to the number shown. More or less pads and wire bonds may be provided, for example, depending on the type of semiconductor chip 32. Also, the positioning of the pads along the top surface of the semiconductor chip 32 may be changed and the positioning of the leads of the lead frame 42 relative to the window frame 44 changed accordingly. Additionally, although the leads are positioned at ninety degrees relative to each other, different positioning may be provided. The leads also may be shaped and sized differently.

The chip package 40 may be constructed having an industry standard footprint, for example, configured as an A0-457 package (available from Kyocera) with the leads positioned in a standard configuration and semiconductor chip 32 being a bottom-side isolated vertical transistor with top-side terminals. Accordingly, the package dimensions and connections can conform to industry standards for non-insulated chip packages while packaging a vertical semiconductor transistor.

Thus, the various embodiments of the invention may be used, for example, to package a power MOSFET 20 as shown in FIG. 9. The power MOSFET 20 is configured to mount directly to a non-insulating package. The power MOSFET 20 may be mounted directly within the package, for example, to a copper-tungsten flange as described in more detail below. The power MOSFET 20 has a vertical structure and the voltage rating of the power MOSFET 20 is a function of doping and thickness (in particular of the N epitaxial layer) and the current rating is a function of a semiconductor channel width within the power MOSFET 20. Accordingly, the power MOSFET 20 can sustain high blocking voltage (e.g., 200 volts) at a high current (e.g., 120 amperes) using a compact piece of silicon.

In operation, and as is known, when a bias voltage is applied to a gate 22 of the power MOSFET 20, electrical current flow is provided from one or more sources 24 of the power MOSFET 20 to one or more drains 26 of the power MOSFET 20 (only a single drain 26 is illustrated). The power MOSFET 20 may operate at different voltage levels, for example, at voltages up to about 200 volts. The power MOSFET 20 packaged in accordance with various embodiments of the invention may be used, for example, in any type of switching operation application wherein the power MOSFET 20 is switched between an on and off state. For example, the power MOSFET 20 or any transistor may be packaged and used in RF communication systems having high frequency operation.

The terminals of the power MOSFET 20, for example, the gate 22, source 24 and drain 26 of the power MOSFET 20 are formed on a top surface of the semiconductor chip, such as shown in FIG. 9. Any suitable semiconductor fabrication process may be used to form the transistor device with metallizations on the top surface defining the terminals. For example, the power MOSFET 20 may include terminals all formed on a top surface using a double diffused metal oxide semiconductor (DMOS) transistor process and having integrated isolation on a bottom surface as described in co-pending commonly assigned application Ser. No. ______ titled “Vertical Transistor with Integrated Isolation.”

However, as described herein the various embodiments are not limited to use with MOSFETs, but may be used with other transistor devices, for example, bipolar junction transistors having a collector, emitter and base instead of the drain, source and gate of the MOSFET 20.

The various embodiments of the invention provide a non-insulated chip package having a standard footprint (e.g., MRF150) or configuration for packaging a vertical structure transistor device. The lead frame of the various embodiments allows top terminals of the transistor device to be connected above the transistor device at different levels. The lead frame also allows, for example, for the transistor device to be connected without a ground (e.g., floating ground) or for other components, such as a resistor, to be connected to the lead frame to provide bias to one or more of the terminals of the transistor device. Further, because the flange of the chip package is electrically isolated from the leads (i.e., no terminals wire bonded to the flange), the chip package may be used, for example, in non-source grounded amplifier technologies and switching power supplies. Also, no insulation layer (e.g., BeO layer) is needed, thereby resulting in improved thermal performance without the use of hazardous materials for the insulation layer.

It also should be noted that although the various embodiments have been described in connection with chip packages for a MOSFET device having a vertical structure, the chip packages of the various embodiments described herein may be implemented in connection with any transistor device. For example, in the embodiment shown in FIG. 8, the semiconductor chip 32 may be a Laterally Diffused Metal Oxide Semiconductor (LDMOS) chip (or equivalent) with ground provided on a bottom surface of the chip. When using an LDMOS chip the source leads 94 are bonded directly to the flange 46. Thus, a non-isolated package results, but the package can still be provided in an industry standard footprint that current LDMOS arrangements do not provide.

Modifications and variations to the various embodiments are contemplated. For example, the positioning and size of the components, terminals and leads may be modified based on the particular application, use, etc. The modification may be based on, for example, different desired or required packaging or operating characteristics.

Accordingly, it is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description.

The scope of the various embodiments of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. §112, sixth paragraph, unless and until such claim limitations expressly use the phrase “means for” followed by a statement of function void of further structure.

1. A chip package comprising:
a flange configured to mount thereon a semiconductor device;
a frame mounted on said flange; and
an inverted bridge lead frame mounted on said frame and positioned above the flange and having a recessed area below a top portion, the inverted bridge lead frame providing semiconductor device terminal connections to at least one lead, wherein said inverted bridge lead frame does not directly contact said flange.

2. A chip package in accordance with claim 1 wherein the recessed area comprises lower connection portions and the inverted bridge lead frame further comprises angled portions between the top portion and the lower connection portions.

3. A chip package in accordance with claim 1 wherein the inverted bridge lead frame is configured to provide lead connections at different levels.

4. A chip package in accordance with claim 1 wherein the inverted bridge lead frame comprises an opening configured to receive therethrough the semiconductor device.

5. A chip package in accordance with claim 1 wherein the flange is non-insulated.

6. A chip package in accordance with claim 1 wherein the semiconductor device comprises a transistor having a drain, a gate and a source and wherein the top portion of the inverted bridge lead frame is configured to connect to drain and gate wires and the recessed area is configured to connect to source wires.

7. A chip package in accordance with claim 1 wherein the inverted bridge lead frame comprises a source portion comprising two leads connected to the recessed area.

8. A chip package in accordance with claim 7 wherein source wire bonds connect to the recessed area.

9. A chip package in accordance with claim 1 wherein terminal wires extend in the same direction from the top portion and the recessed area.

10. A chip package in accordance with claim 1 wherein the semiconductor device comprises a vertical structure transistor.

11. A chip package in accordance with claim 1, wherein the inverted bridge lead frame is supported by the frame.

12. A chip package in accordance with claim 11 wherein the flange, frame and inverted bridge lead frame are configured in a standard footprint.

13. A lead frame for a chip package, the lead frame comprising:
a planar top portion having a plurality of leads; and
a recessed area having a lower connection portion, the lower connection portion in a parallel and lower plane to the planar top portion, wherein said plurality of leads of said top portion and said lower connection portion comprise connection terminals that extend in the same direction.

14. A lead frame in accordance with claim 13 further comprising a source portion having the recessed area and comprising a plurality of source leads.

15. A lead frame in accordance with claim 14 wherein the planar top portion comprises at least one drain lead and at least one gate lead.

16. A lead frame in accordance with claim 13 further comprising angled portions extending downward from the planar top portion to the lower connection portion.

17. A lead frame in accordance with claim 16 wherein the angled portions are inwardly angled.

18. A lead frame in accordance with claim 13 wherein the lower connection portion comprises planar connection regions.

19. A lead frame in accordance with claim 13 wherein the recessed area comprises an opening.

20. A method for packaging a semiconductor device, the method comprising:
mounting a semiconductor transistor device to a flange;
mounting a frame to said flange; and
connecting terminals of the semiconductor transistor device to an inverted bridge lead frame, wherein (i) said inverted bridge lead frame is mounted on said frame and positioned above said flange, and (ii) said inverted bridge lead frame does not directly contact said flange, (iii) source terminal connections of said semiconductor transistor are below both drain and gate terminal connections.
